(19) United States
(12) Patent Application Publication
(10) Pub. No.: US 2026/0331418 A1
(43) Pub. Date: Oct. 22, 2026

(54) PARTICLE BEAM DEVICE AND METHOD THEREFOR

(71) Applicant: Carl Zeiss Microscopy GmbH, Jena (DE)

(72) Inventor: Erik Essers, Aalen (DE)

(21) Appl. No.: 19/529,498

(22) Filed: Feb. 4, 2026

(30) Foreign Application Priority Data
Feb. 10, 2025 (DE) 10 2025 104 740.5

(51) Int. Cl. H01J 37/29; H01J 37/14; H01J 37/147; H01J 37/20; H01J 37/30

(52) U.S. Cl. CPC H01J 37/292; H01J 37/14; H01J 37/1475; H01J 37/1477; H01J 37/20; H01J 37/3002; H01J 2237/24475

(57) ABSTRACT

A method for examining an object using a particle beam device comprises generating a configuration of electrostatic and magnetic fields. The magnetic fields are generated using a magnetic lens. The electric fields are generated between a ring electrode, which surrounds an axis of symmetry of the magnetic lens in ring-shaped fashion, and an object. An angle between a surface normal of the object and the axis of symmetry is greater than 20° such that the electric fields are unsymmetrical. The unsymmetrical electric fields are used to separate trajectories of electrons with different kinetic energies. Different detectors are used to detect the separate trajectories of electrons with different kinetic energies. For example, a secondary electron image and a backscattered electron image may then be generated using two different detectors.

### CROSS-REFERENCE TO RELATED APPLICATIONS

This application claims benefit under 35 U.S.C. § 119 to German Application No. 10 2025 104 740.5, filed Feb. 10, 2025. The entire disclosure of this application is incorporated by reference herein.

### FIELD

The present disclosure relates to methods for examining objects using particle beam devices and particle beam devices for carrying out such methods.

### BACKGROUND

An electron beam microscope is an example of a particle beam device. An electron beam microscope comprises an electron beam source for generating an electron beam which is directed at an object to be examined. The interaction of the electrons in the electron beam incident on the object with the object leads to electrons emerging from the object in turn, and these emergent electrons are detected using a detector. These electrons emerge from the object with different energies, and the intensities of the electrons emerging from the object with different kinetic energies depend on the properties of the object at the location of incidence of the electron beam. If the electron beam is raster-scanned over the object and the intensities of the electrons generated in the process are recorded in a location-dependent manner, then the data obtained represent an electron-microscopic image from which properties of the examined object can be determined.

The particle beam is focused on the surface of the object by provided magnetic and electric fields so as to scan the object with the smallest possible beam spot in order to achieve a high spatial resolution. A particle-optical lens which provides electrostatic and magnetic fields is used to focus the electron beam. The electrons emerging from the object are also influenced by these fields on their way to the detector, which may be integrated into the particle-optical lens for example.

In many cases, the object to be examined is arranged in such a way that the electron beam is incident orthogonally on the surface of the object. However, there are also situations in which the electron beam is incident on the surface of the object at an angle. For example, this is the case when the intention is to not only examine the object with the electron microscope but also process the object using an ion beam, for example. In that case, an ion beam which is directed at the same region of the object that can also be scanned by the electron beam is generated in the vicinity of the electron microscope by an ion beam column. In this context, it may be desirable to orient the surface of the object in such a way that the ion beam is incident orthogonally thereon, and so the electron beam of the electron beam microscope is incident obliquely on the surface of the object.

It has been found that the electron-microscopic images obtained in such configurations do not meet all expectations with respect to clarity and informative value.

### SUMMARY

The present disclosure proposes a method for examining an object using a particle beam device which improves and extends the possibilities of the particle beam device.

According to an aspect, the disclosure provides a method for examining an object using a particle beam device comprises directing a particle beam at locations on a main surface of an object and generating electrons, which emerge from the main surface of the object, using the particles in the particle beam incident on the object. At least one electron detector with a first effective detection area is provided for the detection of electrons that emerge from the object.

A configuration of electrostatic and magnetic fields is generated in the vicinity of the object and selectively influences the electrons generated at the object such that a portion of the generated electrons is incident on the first detection area and another portion of the electrons generated is not incident on the first detection area. The method further comprises using detection signals for generating a first particle-microscopic image. The detection signals are generated by the electrons incident on the first detection area. The configuration of electrostatic and magnetic fields is generated by virtue of generating a current which flows through a coil in a magnetic lens. The magnetic lens comprises pole ends arranged with rotational symmetry in relation to an axis of symmetry of the magnetic lens, and the coil extends around the axis of symmetry of the magnetic lens. Further, the configuration of electrostatic and magnetic fields is generated by applying a voltage between a ring electrode and the object, the ring electrode surrounding the axis of symmetry of the magnetic lens in ring-shaped fashion.

According to exemplary embodiments, the object comprises a main surface with a surface normal that intersects the axis of symmetry of the magnetic lens, with a smallest angle between the surface normal and the axis of symmetry being greater than 20°, such as greater than 30°, for example greater than 40°.

The generated configuration of electrostatic and magnetic fields can also be used to focus an electron beam, which passes through the magnetic lens along the axis of symmetry, on the main surface of the object such that this electron beam is the particle beam which generates the electrons which emerge from the main surface.

According to exemplary embodiments, the generated electrons are influenced using the configuration of electrostatic and magnetic fields in such a way that the electrons generated in this way are accelerated and pass through the opening in the ring electrode and, more precisely, in such a way that electrons in a first portion of the electrons passing through the ring electrode are incident on the first detection area, while electrons in a second portion of the electrons passing through the ring electrode are not incident on the first detection area. This is possible because the electrons emerging from the object move along curved trajectories, the courses of which depend not only on the direction in which the electrons emerge from the object but also on the kinetic energy with which the electrons emerge from the object. Thus, suitable positioning of the effective detection area allows the use of this detection area to detect electrons with specific properties to an increased extent. For example, the effective detection area may be positioned such that electrons emerging from the object with specific kinetic energies are incident thereon in increased proportions such that the generated particle-microscopic image represents certain properties of the object.

The electrons emerging from the object may for example be divided into two groups, specifically a first group whose electrons emerge from the object with a kinetic energy that is less than a threshold value and a second group whose electrons emerge from the object with a kinetic energy that is greater than the threshold value.

According to exemplary embodiments, the first detection area is designed such that a centroid of the first detection area is arranged at a distance from the axis of symmetry and that a ratio of a current of the electrons in the first group of electrons to a current of the electrons in the second group of electrons in the first portion of electrons is, by a factor, greater than or less than a ratio of the current of the electrons in the first group of electrons to a current of the electrons in the second group of electrons in the second portion of electrons. This factor may be greater than 1.5, such as greater than 2.0, for example greater than 5.0, for example greater than 10.

This means that the detection area is designed such that it primarily detects electrons from the first group of electrons emerging from the object, which emerge from the object with kinetic energies that are less than the threshold value or, in an alternative thereto, it primarily detects the electrons from the second group of electrons, which emerge from the object with the kinetic energy that is greater than the threshold value.

According to exemplary embodiments, the first detection area may be designed such that the electrons incident thereon are predominantly what are known as backscattered electrons, or else they are so-called secondary electrons. Accordingly, the generated first particle-microscopic image may be referred to as a backscattered electron image or a secondary electron image. Electrons emerging from the object with a kinetic energy of less than 50 eV are customarily referred to as secondary electrons. Electrons emerging from the object with a kinetic energy of more than 50 eV are typically referred to as backscattered electrons.

According to exemplary embodiments, the particle beam device possibly has further, other detection areas in addition to the first detection area. However, the first particle-microscopic image explained above is predominantly generated on the basis of the detection signals generated by the first detection area, while the detection signals generated by the other detection areas possibly present are not used at all, or only to a small extent, in the generation of the first particle-microscopic image. For example, a number of the detection signals which are used to generate the first particle-microscopic image and are generated by the first detection area of the electron detector is at least 1.5 times greater than the number of the detection signals which are used to generate the first particle-microscopic image and are generated by the possibly present other detection areas. The particle-microscopic image can be divided into a number of pixels. That is to say, it consists of a number of pixels. For example, each pixel has a specific brightness value. This brightness value is determined by the number of detection signals which are assigned to the pixel when the particle-microscopic image is recorded. The sum of the detection signals assigned to the individual pixels over all pixels in the image is the number of detection signals used to generate the first particle-microscopic image.

According to exemplary embodiments, the distance of the centroid of the first detection area from the axis of symmetry is greater than 0.1 times, for example greater than 0.2 times, a greatest distance of the first detection area from the axis of symmetry. This means that the first detection area is not designed to be symmetric with respect to the axis of symmetry and for example is offset with respect thereto in a direction transverse to the axis of symmetry.

According to exemplary embodiments, the method further comprises providing a second effective detection area of the at least one electron detector and using detection signals generated by the electrons incident on the second detection area to generate a second particle-microscopic image. In this case, the second effective detection area is designed in such a way that electrons of at least a part of the second portion of the electrons which pass through the ring electrode, i.e. some of the electrons which are not incident on the first detection area, are incident on the second detection area. In this case, it may be possible, for example, for the first particle-microscopic image to be a backscattered electron image and for the second particle-microscopic image to be a secondary electron image. Alternatively, it is possible for the second particle-microscopic image to be a backscattered electron image and the first particle-microscopic image to be a secondary electron image.

According to exemplary embodiments, the second detection area may also be designed such that a centroid of the second detection area is arranged at a distance from the axis of symmetry. In this case, the distance of the centroid of the second detection area from the axis of symmetry may greater than 0.1 times, for example greater than 0.2 times, a greatest distance of the second detection area from the axis of symmetry.

According to exemplary embodiments, the ring electrode is provided by a pole end of the magnetic lens.

According to exemplary embodiments, the particle beam is complemented by the generation of an ion beam using an ion source, with the ion beam not passing through the magnetic lens and the ring electrode in order to be incident on the main surface of the object. The ion beam is generated in such a way that it is incident on the main surface of the object in a direction that makes a smallest angle with the axis of symmetry that is greater than 20°, for example greater than 30°. The ion beam can be used to modify the object by virtue of material being removed therefrom or deposited thereon by processing with the ion beam.

Embodiments of the disclosure are explained in greater detail below with reference to figures.

### BRIEF DESCRIPTION OF THE DRAWINGS

FIG. 1 shows a schematic cross-sectional view of a particle beam device according to a first embodiment.

FIG. 2 shows a bottom view of detection areas of an electron detector in the particle beam device from FIG. 1.

FIG. 3 shows a schematic cross-sectional view of a particle beam device according to a second embodiment.

FIG. 4 shows a bottom view of a variant of detection areas of an electron detector in the particle beam device from FIG. 3.

FIG. 5 shows a schematic cross-sectional view of a particle beam device according to a third embodiment.

FIG. 6 shows a schematic bottom view of electron detectors in the particle beam device from FIG. 5.

### DETAILED DESCRIPTION

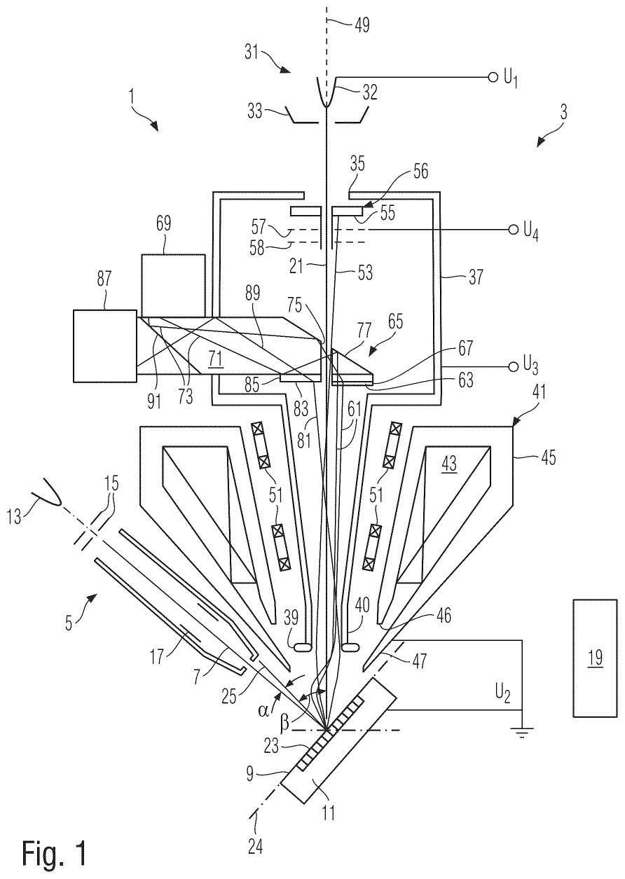

An example of a particle beam device 1 is depicted schematically in cross section in FIG. 1. The particle beam device 1 comprises an electron beam column 3 and an ion beam column 5. The ion beam column 5 generates an ion beam 7, which is directed at an object 9 attached to an object holder 11.

The ion beam column 5 comprises an ion source 13 which emits ions, for example gallium ions. The ions emitted by the ion source 13 are accelerated by electrodes 15 and shaped to form the ion beam 7, which emerges from the ion beam column 5 and can be incident on the object 9. The ion beam column 5 further comprises deflection electrodes 17 which are controlled by a controller 19 of the particle beam device 1 in order to deflect the ion beam 7 such that it can be directed at selectable locations on the object within a working region on the surface of the object 9.

Targeted manipulations are performed on the object 9 with the aid of the controlled ion beam 7. For example, the ions incident on the object 9 are used to remove material from the object 9. Furthermore, a process gas may be brought into the vicinity of the object 9, the process gas being activated by the ions in the ion beam in order to generate material deposits on the object 9.

The electron beam column 3 is provided for observing the manipulations performed on the object 9 with the ion beam 7. Therefore, the electron beam column 3 is designed as an electron microscope which generates an electron beam 21 directed at the object 9. The electrons in the electron beam 21 which are incident on the object 9 generate different types of electrons, which emerge from the object 9 and substantially differ in terms of their kinetic energy with which they emerge from the object 9 and in terms of the direction in which they emerge from the object 9. Some of the electrons emerging from the object 9 are detected by electron detectors of the electron microscope 3, which are described in detail below, for example in order to generate electron-microscopic images from which the progress of the manipulation of the object 9 with the ion beam 7 becomes evident.

The object 9 has a main surface 23, which extends substantially in a plane 24. A surface normal of the main surface 23 at the incidence location of the ion beam 7 on the object 9 is provided with the reference sign 25 in FIG. 1. An angle α between the surface normal 25 and the direction of the ion beam 7 at the location of the incidence of the ion beam 7 on the main surface 23 of the object 9 is at most a few degrees such that the ion beam 7 is incident approximately orthogonally on the main surface 23 of the object 9.

Even though the main surface of the object extends substantially along the plane 24, the object 9 is not precluded from carrying microscopic structures on the surface. For example, peaks and troughs may be formed on the surface of the object 9, the heights and depths of which are a few micrometres.

The electron microscope 3 comprises an electron beam source 31, which generates the electron beam 21. An electric potential U1 is supplied by the controller 19 to an electron emitter 32 of the electron beam source 31. An electric potential U2, which is the ground potential in the example shown in FIG. 1, is supplied by the controller 19 to the object 9. The difference between the potentials U1 and U2 determines the kinetic energy with which the electrons in the electron beam 21 are incident on the object. This kinetic energy may range from 10 eV to 50 keV. Certain desirable performance characteristics achievable with the particle beam device 1 explained herein can emerge for example when the kinetic energy ranges from 0.5 keV to 20 keV, and for example ranges from 0.8 keV to 2.5 keV.

The electron beam source 31 further comprises an extraction electrode 33, which extracts the electrons making up the electron beam 21 from the electron emitter 32 and shapes these to form the electron beam 21. The electrons in this electron beam 21 are accelerated towards an anode 35, which is provided at an upper end of a beam tube 37 in FIG. 1. An electric potential U3 is supplied to the anode 35 and the beam tube 37 by the controller 19 such that the electrons of the electron beam 21 are accelerated through the anode 35 into the beam tube 37 and pass through the beam tube 37 in the longitudinal direction thereof, until they emerge from the beam tube 37 through a ring electrode 39 formed at a lower end 40 of the beam tube 37 in FIG. 1. Following the emergence from the beam tube 37 through the ring electrode 39, the electrons in the electron beam 21 are decelerated in the electric field between the ring electrode 39, which is at the electric potential U3, and the object 9, which is at the electric potential U2.

The electron microscope 3 comprises a magnetic lens 41 for focusing the electron beam 21 on the main surface 23 of the object 9. The magnetic lens 41 comprises a coil 43 which encompasses the electron beam 21 and which is supplied with an excitation current by the controller 19 in order to generate a magnetic field. This magnetic field is guided in a yoke 45 which is situated in the magnetic lens 41 and which, in the cross section of FIG. 1, comprises a first pole end 46 and a second pole end 47. The two pole ends 46 and 47 extend around the electron beam 21 and are arranged symmetrically with respect to an axis of symmetry 49 of the magnetic lens 41, i.e. arranged centred with respect thereto. The magnetic field generated by the coil 43, guided in the yoke 45 and emerging at the pole ends 46 and 47 can focus the electron beam 21. The second pole end 47 is also at a defined electric potential. In the example shown in FIG. 1, the electric potential of the second pole end 47 is the same as the electric potential U2 of the object 9, but the electric potential of the second pole end 47 may also differ from the electric potential U2 of the object 9. In both cases, the electric potential of the second pole end 47 differs from the electric potential U3 of the beam tube 37. The pole end 47 surrounds the axis of symmetry 49 of the magnetic lens 41 in ring-shaped fashion and acts as a ring electrode which influences the electron beam 21.

An angle β between the surface normal 25 and the axis of symmetry 49 differs significantly from zero and is greater than 20° and for example greater than 30°.

The electron microscope 3 further comprises beam deflectors 51, which are excited by the controller 19 in order to deflect the electron beam 21 in such a way that it is incident on the main surface 23 of the object 9 at a selectable incidence location. The electrons, which are generated by the electrons in the electron beam 21 incident on the object 9 and which emerge from the object and are detected by detectors of the electron microscope 3 described below, may then be captured in a manner assigned to the respective incidence locations. A data record of the signal intensities detected when a part of the surface of the object 9 is scanned represents an electron-microscopic image of this part of the object.

The electrons generated by the electrons in the electron beam 21 differ in terms of the direction in which they emerge from the object 9 and in terms of the kinetic energy with which they emerge from the object 9. FIG. 1 shows exemplary trajectories of three different types of electrons which emerge from the object 9, with these three types basically differing in terms of the kinetic energy with which the electrons emerge from the object 9 and in terms of the direction in which the electrons emerge from the object 9.

Reference sign 53 in FIG. 1 denotes an exemplary trajectory of a backscattered electron, which emerges from the object 9 in such a direction that it enters the beam tube 37 through the ring electrode 39 and is incident on a detection area 55 of an electron detector 56. In this case, the trajectory 53 of the electron is influenced by the electric field between the ring electrodes 39 and 47 and the main surface 23 of the object 9 and by the magnetic field of the magnetic lens 41. The electric field which decelerates the electrons in the electron beam 21 between their emergence from the beam tube 37 through the ring electrode 39 and their incidence on the surface 23 of the object 9 accordingly accelerates the electrons emerging from the object 9, which are incident on the detection area 55 of the electron detector 56. The magnetic field which is generated by the magnetic lens 41 and focuses the electron beam 21 on the surface 23 of the object 9 also influences the electrons which emerge from the object 9 and are incident on the detection area 55 of the detector 56 since these electrons are collimated by the magnetic field, and so backscattered electrons which emerge from the object in a manner directed into a restricted solid angle range pass through the ring electrode 39 and can reach the detection area 55.

The electron detector 56 of the example explained here also comprises two electrodes 57 and 58, which are arranged between the object 9 and the detection area 55 and are each formed by a grid. The electrode 58 and also the detection area 55 are at the electric potential U3 of the beam tube 37, while an adjustable potential U4 is supplied to the electrode 57 arranged between the electrode 58 and the detection area 55 by the controller 19. Hence the electrode 57 may be used to select the electrons 53 that reach the detection area 55 on the basis of their kinetic energy by virtue of modifying the potential U4.

Reference sign 61 in FIG. 1 denotes two trajectories of low-energy secondary electrons by way of example, which emerge from the main surface 23 of the object 9 at two different angles. In comparison with backscattered electrons, the trajectories of which are represented by way of example by the trajectory 53 in FIG. 1, the low-energy secondary electrons are influenced to a substantially greater extent by the electric field between the ring electrodes 39 and 47 and the surface 23 of the object. The electric field between the ring electrodes 39 and 47 and the main surface 23 of the object is significantly unsymmetrical with respect to the axis of symmetry 49 in its lower region close to the object 9 since the angle β between the surface normal 25 and the axis of symmetry 49 is greater than 20°.

In the illustration of FIG. 1, the low-energy secondary electrons 61 cross the axis of symmetry 49 before or after passing through the ring electrode 39 and move upwards on the right-hand side of the axis of symmetry 49 in the illustration of FIG. 1. There, they are incident on a first detection area 63 of an electron detector 65. The first detection area 63 of the electron detector 65 is provided on a scintillator body 67, which generates light from the electrons incident on the first detection area 63. This light generated in the scintillator body 67 is emitted in all possible spatial directions and should reach a light detector 69. A light guide 71 is provided to this end, the latter being optically coupled to the scintillator body 67 at one end and to the light detector 69 at the other. Reference sign 73 in FIG. 1 denotes two exemplary trajectories of light which is generated by the scintillator body 67 and reaches the light detector 69. The light guide 71 has a bore 75 centred with respect to the axis of symmetry 49, the bore firstly allowing the passage of the electrons in the electron beam 21 to the object 9 and secondly enabling the passage of the electrons, which were generated at the object 9 and reach the detection area 55 of the electron detector 56, through the light guide 71. Furthermore, in the sectional illustration shown in FIG. 1, the light guide 71 comprises a region 77 which widens from right to left in the shape of a wedge and in which a surface of the light guide 71 is oriented in such a way that the light is reflected to the left in the figure and towards the light detector 69.

Reference sign 81 in FIG. 1 represents an exemplary trajectory of a backscattered electron emerging from the object 9. On account of its higher kinetic energy when emerging from the object 9, this electron is influenced less by the unsymmetrical electric field between the ring electrode 39 and the surface 23 of the object 9 than the trajectories 61 of the low-energy secondary electrons. In the illustration of FIG. 1, the backscattered electron with the trajectory 81 reaches the left-hand side of the axis of symmetry 49 and is incident on a second detection area 83 of the electron detector 65. The second detection area 83 is provided on a scintillator body 85 which generates light by way of incident electrons. The scintillator body 85 is likewise optically coupled to the light guide 71 such that the generated light is able to enter the latter in order to reach a light detector 87 which is likewise optically coupled to the light guide 71. Reference sign 89 in FIG. 1 denotes by way of example a trajectory of the light which is generated in the scintillator body 85 and reaches the light detector 87.

The second detection area 83 is provided only on a part of the surface of the scintillator body 85 facing the object 9. The other part of this surface carries the scintillator body 67, which provides the first detection area of the electron detector 65, and is optically coupled thereto. Hence the scintillator body 67 is coupled to the light guide 71 by way of the scintillator body 85.

The scintillator bodies 67 and 85 are made from different scintillator materials which generate light of different wavelengths from incident electrons. A dichroic layer 91 adapted to this wavelength is provided in the light guide and reflects the light 73 generated by the scintillator body 67 such that it does not reach the light detector 87 but reaches the light detector 69. The dichroic layer 91 allows the light 89 generated by the scintillator body 85 to pass such that it reaches the light detector 87 instead of being reflected at the light detector 69.

Hence the electrons which are incident on the first detection area 63 of the electron detector 65 and which are low-energy secondary electrons initially generate detection signals in the form of the light 73, which are converted by the light detector 69 into electrical signals read by the controller and used to generate a first particle-microscopic image. Similarly, the electrons incident on the second detection area 83 of the electron detector 65, the backscattered electrons, initially generate detection signals in the form of the light 89, which is converted by the light detector 87 into electrical signals which are likewise read by the controller and used to generate a second particle-microscopic image.

The first and second particle-microscopic images differ in terms of the kinetic energies of the electrons which emerge from the object 9 and the detection signals of which are used to generate the images. The first particle-microscopic image may be referred to as a secondary electron image, and the second particle-microscopic image may be referred to as a backscattered electron image.

Backscattered electrons are incident to the same extent on the first detection area 63 and the second detection area 83 as they are influenced comparatively little by the unsymmetrical electric field. On account of their substantially lower kinetic energy, secondary electrons are influenced comparatively more by the unsymmetrical electric field and basically are not incident on the second detection area 83, for which reason the detection signal generated by the second detection area 83 is basically determined by the incident backscattered electrons and may be used as a signal that represents the intensity of the backscattered electrons.

Most secondary electrons are incident on the first detection area 63. Furthermore, the number of secondary electrons generated and entering the beam tube 37 is normally substantially greater than the number of backscattered electrons generated and entering the beam tube 37. Therefore, the detection signal generated by the first detection area 63 is basically dominated by the incident secondary electrons despite the backscattered electrons also being incident on the first detection area 63, and the signal may be used as a signal which represents the intensity of the secondary electrons.

The secondary electrons and the backscattered electrons are thus two groups of electrons which differ in terms of their kinetic energy when emerging from the object 9. The separation of the electrons emerging from the object 9 into the two groups may be implemented on the basis of a threshold value of the kinetic energy. For example, the customary value of 50 eV may be used as the threshold value.

The first detection area 63 and the second detection area 83 are designed such that the detection signal from the first detection area 63 represents the intensity of the secondary electrons to the best possible extent, and the detection signal of the second detection area 83 represents the intensity of the backscattered electrons to the best possible extent.

For example, a ratio of a current of the electrons in the first group of electrons to a current of the electrons in the second group of electrons in a first portion of electrons, which are incident on the first detection area 63, is, by a factor, greater than or less than a ratio of the current of the electrons in the first group of electrons to a current of the electrons in the second group of electrons in a second portion of electrons, which are incident not on the first detection area 63 but on the second detection area 83 instead. This factor may for example be greater than 1.5, such as greater than 2.0, for example greater than 5.0 and for example greater than 10.

The separation of the trajectories of the electrons in the first group of electrons from the trajectories of the electrons in the second group of electrons is implemented inter alia by the electrostatic field generated between the ring electrodes 39 and 47 and the main surface 23 of the object 9. The electrostatic field is not symmetrical to the axis of symmetry 49 on account of the tilt of the main surface 23 of the object 9. However, it is substantially symmetrical to the plane of the drawing in FIG. 1.

The magnetic field of the magnetic lens 41 leads to a Larmor rotation of the trajectories of the electrons about the axis of symmetry 49, for which reason the trajectories of the electrons cannot actually lie in a plane. The illustration in FIG. 1, which shows trajectories in the plane of the drawing, is not correct insofar as the Larmor rotation is not illustrated. On account of this Larmor rotation, the first detection area 63 is not actually arranged to the right of the axis of symmetry 49 either, unlike what is shown in the schematic illustration of FIG. 1, and the second detection area 83 is not actually arranged to the left of the axis of symmetry 49. The actual geometry of the first detection area 63 and of the second detection area 83 is determined by an optimization calculation such that the separation of the two groups of electrons is as good as possible. For example, the optimization calculation may be implemented in such a way that the aforementioned factor is maximized. For example, the optimization calculation may comprise a ray tracing method, in which the movement of a large number of electrons emerging from the object with different energies and in different directions is simulated. In this case, the forces exerted by the electrostatic field and the magnetic field that act on the electrons are taken into account such that the trajectories obtained therewith also reproduce the Larmor rotation.

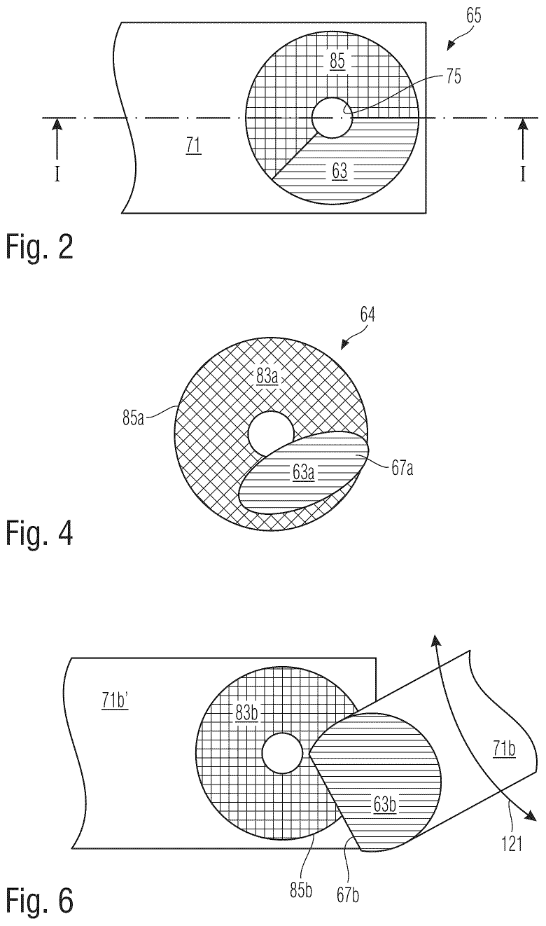

FIG. 2 shows a schematic bottom view of the first detection area 63 and the second detection area 83 of the electron detector 65. It is evident that the two detection areas 63 and 83 are not arranged symmetrically with respect to the plane of the drawing in FIG. 1, which is represented by a line II.

Further embodiments of the particle beam device and of the operating method are explained below. In this case, components which correspond to those of the particle beam device shown in FIGS. 1 and 2 in terms of their structure or function are provided with the same reference numerals, but supplemented with an additional letter. In order to avoid repetitions, not all details are described repeatedly here, but basicaly the differences from the preceding embodiments are explained. For understanding all details, reference should therefore be made to the description of the respective preceding embodiments and the introduction of the description.

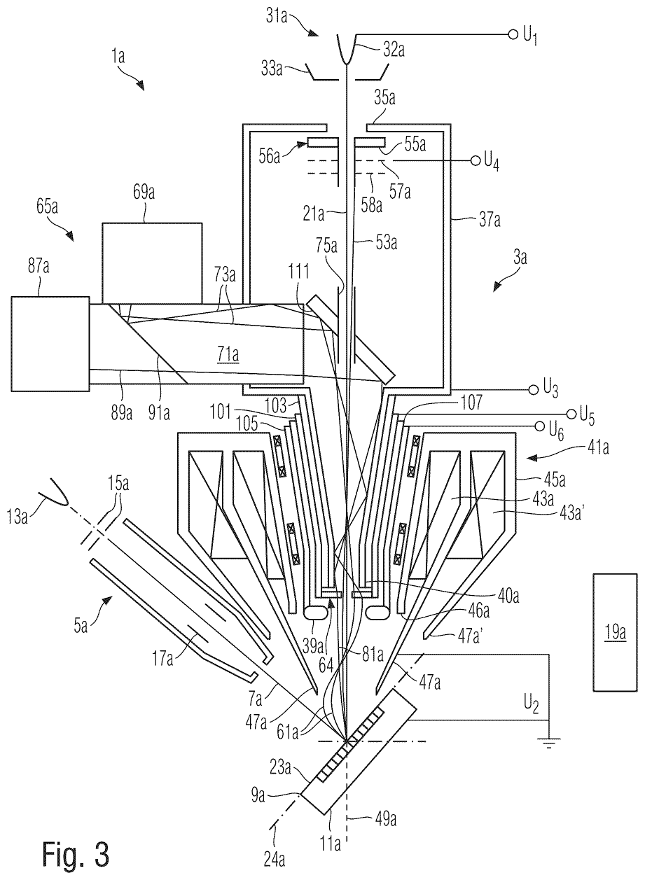

FIG. 3 schematically shows a particle beam device 1a, which in turn comprises an electron beam microscope 3a and an ion beam column 5a. The ion beam column 5a generates an ion beam 7a, which is incident substantially orthogonally on a main surface 23a of an object 9a and which can be directed at selectable locations on the object in order to remove material from the object or deposit material on the object 9a.

The electron beam microscope 3a comprises an electron beam source 31a for generating an electron beam 21a, the latter entering into a beam tube 37a, passing through the latter and emerging from the beam tube 37a at a lower end 40a of the beam tube 37a in order to be incident on the object 9a. A scintillator arrangement 64 of an electron detector 65a is arranged between the lower end 40a of the beam tube and the object 9a and comprises a central opening through which the electron beam 21a passes. A ring electrode 39a whose central opening is passed by the electron beam 21a before the latter is incident on the object 9a is arranged between the scintillator arrangement 64 and the object 9a.

An electric potential U3 is supplied to the beam tube 37a by a controller 19a.

The scintillator arrangement 64 is held on a sleeve 101 which surrounds the beam tube 37a on the outside and which is electrically insulated from the beam tube 37a by an insulator 103. An electric potential U5 is supplied to the sleeve 101 by the controller 19a such that the scintillator arrangement 64 is also at the potential U5.

The ring electrode 39a is held by a sleeve 105 which surrounds the sleeve 101 and which is electrically insulated from the latter by an insulator 107. An electric potential U6 is supplied to the sleeve 105 by the controller 19a such that the ring electrode is also at the potential U6.

According to an example, the potential U3 is equal to 8 kV, the potential U5 is equal to 9 kV, and the potential U6 is equal to 10 kV. Other values for the potentials U3, U5 and U6 are possible. The potentials U3, U5 and U6 can be used to set the electric fields, which firstly decelerate and focus the electron beam 21a on its path to the object 9a and secondly influence the electrons emerging from the object 9a on their path to the various detection areas on the detectors of the electron microscope 3a, in such a way that various groups of electrons emerging from the object 9a are predominantly incident on different detection areas. These functions may be optimized with regard to different targets by setting the potentials U3, U5 and U6.

The electron beam microscope 3a further comprises a magnetic lens 41a having two coils 43a and 43a', which are arranged between three pole ends 46a, 47a and 47a′. The pole ends 46a, 47a and 47a′ are arranged symmetrically with respect to an axis of symmetry 49a of the magnetic lens 41.

The pole ends 46a, 47a and 47a′ are at an electric potential U2, which is the ground potential, just like the object 9a.

A bottom view of the scintillator arrangement 64 of the electron detector 65a is schematically illustrated in FIG. 4. The scintillator arrangement 64 has the shape of a circular disk with a central opening. The scintillator arrangement 64 comprises a first scintillator body 67a, which provides a first detection area 63a of the electron detector 65a, and a second scintillator body 85a, which provides a second detection area 83a of the electron detector 65a. The two detection areas 63a, 83a are designed such that different groups of electrons emerging from the object 9a, the groups differing in terms of the kinetic energies of the electrons, are predominantly incident on different ones of the two detection areas 63a, 83a, as has been explained in more detail above.

Reference sign 61a in FIG. 3 denotes two trajectories of low-energy secondary electrons by way of example, which emerge from the main surface 23a of the object 9a at two different angles. The secondary electrons of these trajectories 61a are incident on the first detection area 63a and generate light in the scintillator body 67a.

Reference sign 81a in FIG. 3 denotes by way of example a trajectory of a backscattered electron that emerges from the main surface 23a of the object 9a. This trajectory 81a is incident on the second detection area 83a and generates light in the scintillator body 85a.

Reference sign 73a in FIG. 3 denotes two exemplary trajectories of light which is generated by the scintillator body 67a and reaches a light detector 69a of the electron detector 65a. Reference sign 89a in FIG. 3 denotes an exemplary trajectory of light which is generated by the scintillator body 85a and reaches a light detector 87a of the electron detector 65a. The light generated by the scintillator body 85a differs from the light generated by the scintillator body 67a in terms of the wavelength since the scintillator bodies 67a and 85a are made of different scintillator materials.

In this case, the light generated by the two scintillator bodies 67a and 85a is reflected off a mirror 111 arranged in the beam tube 37a. On the path from the scintillator bodies 67a and 85a to the mirror 111, the light may be reflected one or more times off the conical inner wall of the beam tube 37, this design of the inner wall causing the light to be directed more strongly towards the mirror 111 with each reflection. The mirror 111 has a cutout 75a formed by a small tube for the passage of the electron beam 21a.

Following the reflection off the mirror 111, the light enters a light guide 71a in which a dichroic layer 91a is provided; the light generated by the scintillator body 85a passes through the layer so that it reaches the light detector 87a, and the light generated by the scintillator body 67a is reflected off the layer so that it reaches the light detector 69a.

The first detection area 63a and the second detection area 85a of the electron detector 65a in turn are geometrically designed on the scintillator arrangement in such a way that the proportion of the electrons in a first group, which have a lower kinetic energy than a threshold value and are incident on the second detection area 83a, is smaller than a proportion of these electrons that are incident on the first detection area 63a. The designs of the detection areas 63a and 83a may be determined by an optimization calculation, as has already been explained above.

The optimal designs of the detection areas 63a and 83a may differ depending on the application.

In addition to the electron detector 65a, the electron microscope 3a comprises a further electron detector 56a, with electrons that emerged from the object 9a and passed the mirror 111 through its cutout 75a being incident on the detection area 55a of the further electron detector. The electron detector 56a comprises two electrodes 57a and 58a in order to be able to select the kinetic energy of the electrons that reach the detection area 55a.

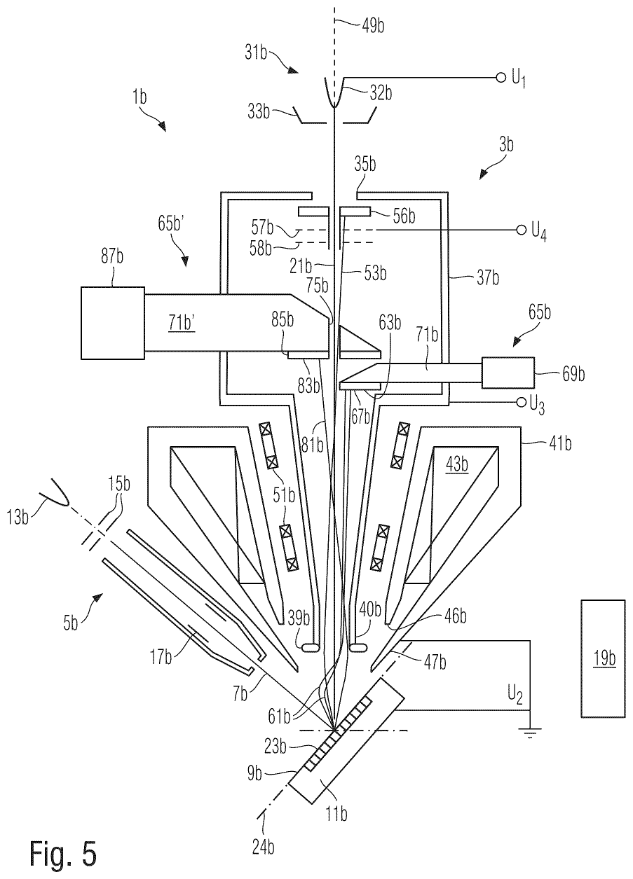

FIG. 5 schematically shows a particle beam device 1b, which in turn comprises an electron beam microscope 3b and an ion beam column 5b. The ion beam column 5b generates an ion beam 7b, which is incident substantially orthogonally on a main surface 23b of an object 9b and which can be directed at selectable locations on the object.

The electron beam microscope 3b comprises an electron beam source 31b for generating an electron beam 21b, the latter entering into a beam tube 37b, passing through the latter and emerging from the beam tube 37b through a ring electrode 39b provided at a lower end 40b of the beam tube 37b in order to be incident on the object 9b.

An electric potential U3 is supplied to the beam tube 37b and the ring electrode 39b by a controller 19b of the particle beam device 1b.

The electron beam 21b is focused by a magnetic lens 41b, and the electrons in the electron beam 21b are decelerated by an electrostatic field prior to their incidence on the object, the field being generated between the ring electrode 39b and the second pole end 47b of the magnetic lens 41b acting as a ring electrode and the main surface 23b of the object 9b, which is at ground potential together with the second pole end 47b.

The electron microscope 3b further comprises an electron detector 56b. The electron detector 56b comprises two electrodes 57b and 58b in order to be able to select the kinetic energy of the electrons that reach its detection area 55b. Reference sign 53b in FIG. 5 denotes a trajectory of a backscattered electron which reaches the detection area 55b.

While the detection areas 63 and 83 of the electron microscope 3 from FIG. 1 and the detection areas 63a and 83a of the electron microscope 3a from FIG. 3 are basically arranged in an identical plane oriented transversely to the axis of symmetry, the electron microscope 3b further comprises an electron detector 65b, which provides a first detection area 63b, and an electron detector 65b′, which provides a second detection area 83b, with the detection areas 63b and 83b being arranged in different planes.

The first detection area 63b is provided on a first scintillator body 67b which is optically coupled to a light guide 71b in order to guide light generated by the scintillator body 67b to a light detector 69b of the electron detector 65b. The second detection area 83b is provided on a second scintillator body 85b which is optically coupled to a light guide 71b′ in order to guide light generated by the second scintillator body 85b to a light detector 87b of the electron detector 65b′.

From the view of the electrons emerging from the object, the scintillator body 67b in this case conceals a part of the detection area of the electron detector 65b′, and so the effective detection area 83b thereof is smaller than its largest possible detection area on account of being shadowed by the scintillator body 67b.

FIG. 6 shows a schematic bottom view of the electron detectors 65b and 65b′.

It is further evident from FIG. 6 that the electron detector 65b is pivotable, as indicated by an arrow 121. By pivoting the electron detector 65b, it is possible to modify the geometries of the effective detection areas 63b and 83b and adapt these to specific operating situations.

In summary, a method for examining an object with a particle beam device is thus proposed. The method comprises generating a configuration of electrostatic and magnetic fields, wherein the magnetic fields are generated using a magnetic lens and the electric fields are generated between a ring electrode, which surrounds an axis of symmetry of the magnetic lens in ring-shaped fashion, and an object, wherein an angle β between a surface normal of the object and the axis of symmetry is greater than 20°, for which reason the electric fields are unsymmetrical. The unsymmetrical electric fields are used to separate trajectories of electrons with different kinetic energies, with different detectors being provided for the detection thereof, and so, for example, a secondary electron image and a backscattered electron image can be generated using two different detectors.

What is claimed is:

1. A method, comprising:
generating a configuration of electrostatic and magnetic fields which by a method which comprises:
generating a current which flows through a coil in a magnetic lens of a particle beam device, the magnetic lens comprising pole ends with rotational symmetry in relation to an axis of symmetry of the magnetic lens, the coil encompassing the axis of symmetry of the magnetic lens; and
applying a voltage between: i) a ring electrode of the particle beam device, the ring electrode surrounding the axis of symmetry of the magnetic lens in ring-shaped fashion; and ii) an object in the particle beam device, the object comprising a main surface with a surface normal that intersects the axis of symmetry of the magnetic lens, a smallest angle between the surface normal and the axis of symmetry being more than 20°;
providing a first detection area of at least one electron detector of the particle beam device, a centroid of the first detection area being a distance from the axis of symmetry;
directing a particle beam produced by the particle beam device at locations on the main surface of the object to generate first and second groups of electrons that emerge from the main surface of the object, electrons in the first group of electrons emerging from the main surface of the object with a kinetic energy that is lower than a threshold value, electrons in the second group of electrons emerging from the main surface of the object with a kinetic energy that is higher than the threshold value;
influencing the electrons using the configuration of electrostatic and magnetic fields so that the electrons generated in this way are accelerated and pass through an opening in the ring electrode, electrons in a first portion of the electrons passing through the ring electrode being incident on the first detection area, electrons in a second portion of the electrons passing through the ring electrode not being incident on the first detection area; and
using detection signals generated by the electrons incident on the first detection area to generate a first particle-microscopic image,
wherein the first detection area is configured so that a ratio of a current of the electrons in the first group of electrons to a current of the electrons in the second group of electrons in the first portion of electrons is, by a factor of more than 1.5, more than or less than a ratio of a current of the electrons in the first group of electrons to a current of the electrons in the second group of electrons in the second portion of electrons.

2. The method of claim 1, wherein a number of the detection signals which are used to generate the first particle-microscopic image and are generated by the first detection area of the electron detector is more than a number of detection signals which are used to generate the first particle-microscopic image and are generated by detection areas of the at least one electron detector other than the first detection area.

3. The method of claim 1, wherein the distance of the centroid of the first detection area from the axis of symmetry is more than 0.1 times a greatest distance of the first detection area from the axis of symmetry.

4. The method of claim 1, wherein the first particle-microscopic image is a backscattered electron image or a secondary electron image.

5. The method of claim 1, further comprising using detection signals generated by electrons incident on a second detection area of the at least one detector to generate a second particle-microscopic image, wherein the second detection area is configured so that at least some electrons of the second portion of the electrons which pass through the ring electrode are incident on the second detection area.

6. The method of claim 5, wherein a centroid of the second detection area is a distance from the axis of symmetry.

7. The method of claim 6, wherein the distance of the centroid of the second detection area from the axis of symmetry is more than 0.1 times a greatest distance of the second detection area from the axis of symmetry.

8. The method of claim 6, wherein the distance of the centroid of the second detection area from the axis of symmetry is more than 0.2 times a greatest distance of the second detection area from the axis of symmetry.

9. The method of claim 5, wherein:
the first particle-microscopic image is a backscattered electron image, and the second particle-microscopic image is a secondary electron image; or
the second particle-microscopic image is a backscattered electron image, and the first particle-microscopic image is a secondary electron image.

10. The method of claim 5, wherein the first detection area and the second detection area are substantially in an identical plane which is transverse to the axis of symmetry.

11. The method of claim 1, wherein the particle beam passes through the magnetic lens and the ring electrode.

12. The method of claim 1, wherein the particle beam is an electron beam.

13. The method of claim 1, further comprising generating an ion beam using an ion source of the particle beam device, wherein:
the ion beam is directed at the locations on the main surface and does not pass through the magnetic lens and the ring electrode; and
a smallest angle between a beam direction of the ion beam incident on the main surface and the axis of symmetry is more than 20°.

14. The method of claim 1, further comprising generating an ion beam using an ion source of the particle beam device, wherein:
the ion beam is directed at the locations on the main surface and does not pass through the magnetic lens and the ring electrode; and
a smallest angle between a beam direction of the ion beam incident on the main surface and the axis of symmetry is more than 30°.

15. The method of claim 13, wherein the particle beam is an ion beam.

16. The method of claim 1, wherein the factor is more than 2.0.

17. The method of claim 1, wherein the factor is more than 5.0.

18. The method of claim 1, wherein the factor is more than 10.

19. The method of claim 1, wherein a number of the detection signals which are used to generate the first particle-microscopic image and are generated by the first detection area of the electron detector is at least 1.5 times more than a number of detection signals which are used to generate the first particle-microscopic image and are generated by detection areas of the at least one electron detector other than the first detection area.

20. The method of claim 1, wherein the distance of the centroid of the first detection area from the axis of symmetry is more than 0.2 times a greatest distance of the first detection area from the axis of symmetry.
